(19) United States
(12) Patent Application Publication
(10) Pub. No.: US 2026/0353544 A1
(43) Pub. Date: Nov. 5, 2026

(54) ELECTRICALLY GROUNDED AND MECHANICALLY SUPPORTED SMT STANDOFFS

(71) Applicant: Raytheon Company, Arlington, VA (US)

(72) Inventors: Brian K. Atwood, MURPHY, TX (US); Eugene C. Shaw, GRAND PRAIRIE, TX (US)

(21) Appl. No.: 19/197,622

(22) Filed: May 2, 2025

(51) Int. Cl. H05K 1/02; H05K 1/11

(52) U.S. Cl. CPC H05K 1/0203; H05K 1/0215; H05K 1/111; H05K 2201/032; H05K 2201/09409; H05K 2201/09418; H05K 2201/2036

(57) ABSTRACT

An assembly for surface mount technology (SMT) applications addresses the challenge of securely attaching electronic assemblies to supporting structures while ensuring electrical grounding. The assembly includes a printed wiring board with a top surface and multiple soldering points extending to ground. A standoff is mounted on the board, thermally coupling a cooling plate to the board. The standoff features several conductive pads forming a pattern that aligns with the soldering points, creating electrical contact and forming cavities between the pads. An epoxy is dispensed in the gaps and cavities, securing the standoff to the board. This design enhances mechanical stability and electrical grounding, making the assembly suitable for applications where through-hole connectors are impractical, such as in radio frequency (RF) designs.

### TECHNICAL FIELD

Examples relate to surface mount technology and more specifically to mounts that can be used in surface mount technology implementations.

### BACKGROUND

In the field of surface mount technology (SMT), securely attaching electronic assemblies to supporting structures is of great importance, especially in applications where through-hole connectors are not feasible due to the potential disruption of internal circuitry. This situation frequently arises in radio frequency (RF) designs, where preserving the integrity of manifold layers is of great importance. Traditional methods of mounting, such as using soldered standoffs, have shown to be inadequate in providing the required mechanical support. These methods often result in detachment during mechanical stress, such as screw insertion or environmental vibrations, which can lead to system failures. Moreover, shearing can occur where standoffs are soldered.

Existing solutions struggle to balance the need for electrical grounding with mechanical stability. The use of large solder pads can lead to issues such as solder voiding, which compromises the strength of the attachment. Additionally, the reliance on perimeter epoxy for reinforcement does not adequately address the shear forces encountered during operation. As a result, there is a pressing need for a more robust and reliable method of securing SMT standoffs to electronic assemblies, one that can withstand the mechanical demands of modern electronic systems while ensuring proper electrical grounding.

### BRIEF DESCRIPTION OF DRAWINGS

FIG. 1 illustrates a spacecraft on which examples described herein may be used.

FIG. 2 shows an assembly having a standoff mounted on a printed wiring board that can be used with the spacecraft of FIG. 1.

FIG. 3 illustrates a gap that can be formed between a periphery of the standoff of FIG. 2 and the printed wiring board of FIG. 2.

FIG. 4 is a bottom view of the standoff in FIG. 2 that shows standoff pads extending from a bottom surface of the standoff.

FIG. 5 is a top view of the printed wiring board in FIG. 2 that shows soldering points extending to a top surface of the printed wiring board.

FIGS. 6A and 6B show a pad pattern and a solder point pattern of the standoff pads and the soldering pads shown with reference to FIGS. 4 and 5.

FIGS. 7-9 show pad patterns and solder point patterns of standoff pads and soldering pads shown with reference to FIG. 2.

### DETAILED DESCRIPTION

The following description and the drawings sufficiently illustrate teachings to enable those skilled in the art to practice them. Other embodiments may incorporate structural, logical, electrical, process, and other changes. Portions and features of some examples may be included in, or substituted for, those of other examples. Teachings set forth in the claims encompass all available equivalents of those claims.

Examples relate to an assembly having a standoff that mounts to a printed wiring board. The standoff can be used to secure a cooling plate to the printed wiring board to cool a plurality of electrical components mounted on the printed wiring board. The standoff can have a plurality of pads extending from a bottom surface. The plurality of pads can form a pad pattern at the standoff bottom surface.

The printed wiring board can have a plurality of soldering points at a top surface thereof. The plurality of soldering points can electrically connect to ground. The plurality of soldering points can have a soldering point pattern that matches the pad pattern. The standoff can couple with the printed wiring board where the plurality of pads can align with the plurality of soldering points such that the standoff connects to ground.

The plurality of pads extend from standoff bottom surface and form cavities between the standoff bottom surface and the printed wiring board top surface. In addition, the plurality of pads can create gaps between a periphery of the standoff at the standoff bottom surface and the printed wiring board top surface. An adhesive, such as epoxy, can be dispensed in the cavities and in the gap and couple the standoff to the printed wiring board. As described herein, an adhesive can also be disposed in the cavities and gaps described herein.

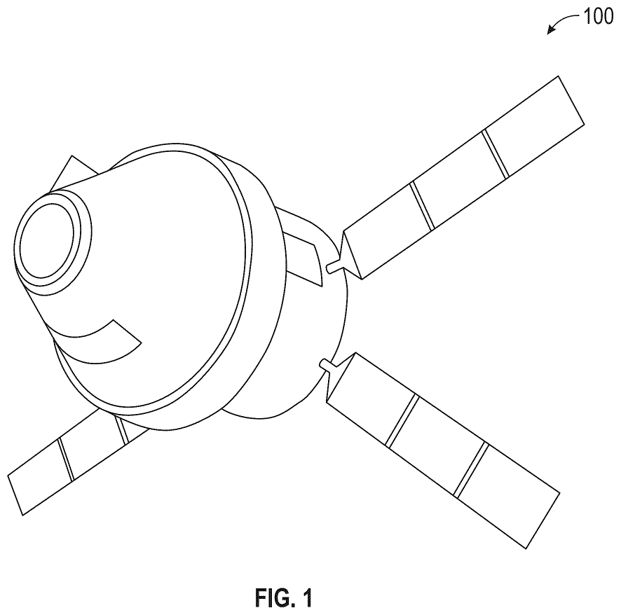

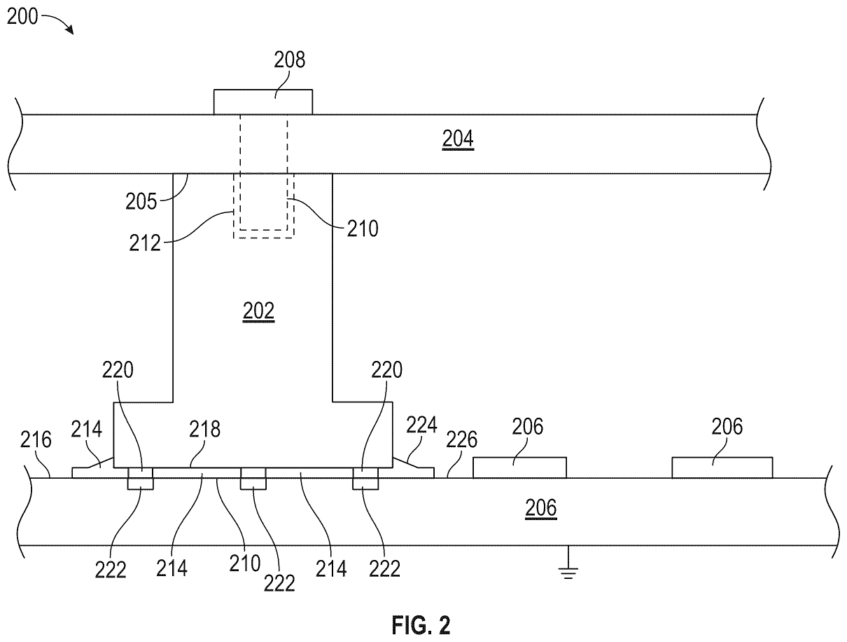

Now referring to FIG. 1, a spacecraft 100 is shown in which an assembly 200 (FIG. 2), which can be a circuit card assembly, can be disposed and used. The spacecraft 100 can be a satellite having an antenna array that implements several electronic cards that are mounted on a single plate. During operation, electronic components on the assembly 200 can generate heat, thereby requiring a cooling mechanism. The assembly 200 can include a standoff 202 that is thermally coupled with a cooling plate 204 that can conduct heat away from electronic components mounted on a printed wiring board 206. The standoff 202 can couple with the cooling plate 204 at a top surface 205 of the standoff 202. Thus, the standoff 202 can thermally couple the cooling plate 204 with the printed wiring board 206. The standoff 202 can be formed from steel, aluminum, or any other type of metal alloy that can facilitate thermal conduction between the cooling plate 204 and the printed wiring board 206.

The standoff 202 can couple with the cooling plate 204 using any type of means, such as a fastening means 208. The fastening means 208 can have a threaded portion 210. The standoff 202 can define a recess 212 having threads that complement threads of the threaded portion 210. While a fastener having a threaded portion is described, any type of fastening means, such as a rivet or the like, can be used to couple the cooling plate 204 to the standoff 202 as shown with reference to FIG. 2.

The standoff 202 can be mounted onto and coupled with the printed wiring board 206 using an adhesive 214 at a top surface 216 of the printed wiring board 206. The adhesive 214 can be an epoxy that is capable of liquifying at a given temperature, expanding into a cavity through capillary action, and forming bonds with the printed wiring board top surface 216 and a bottom surface 218 of the standoff 202 that is opposite the standoff top surface 205. Examples of epoxies that can be used can include thermal expanding epoxies, low viscosity epoxies, capillary flow epoxies, heat-activated epoxies, and the like.

The standoff 202 can include pads 220 that can extend from the standoff bottom surface 218 towards the printed wiring board 206 and the printed wiring board top surface 216. As can be seen with reference to FIG. 2, when the standoff 202 mounts to the printed wiring board 206, the standoff pads 220 can separate the standoff 202 from the printed wiring board 206 and the printed wiring board top surface 216.

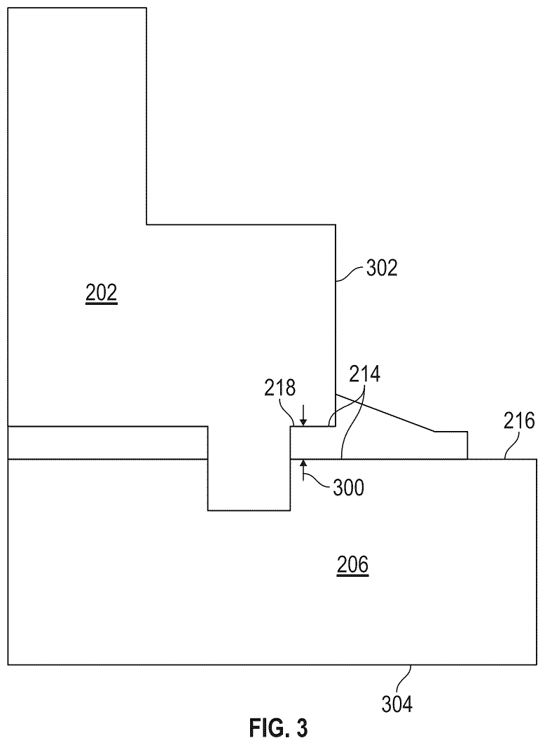

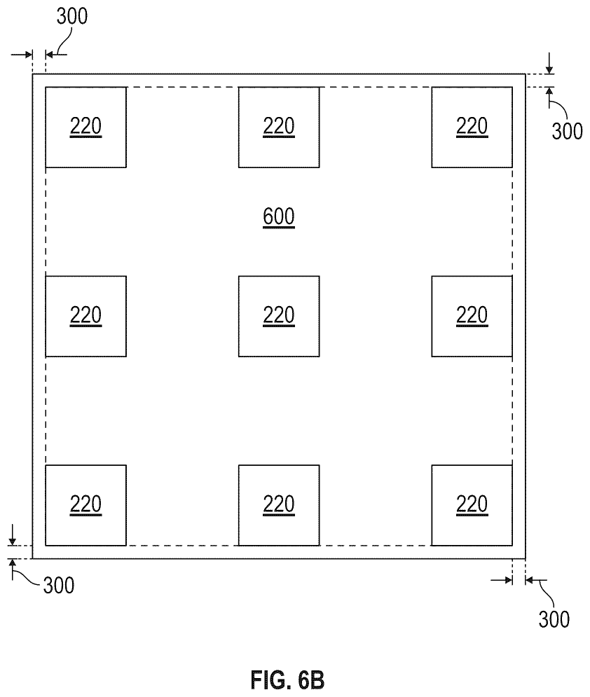

The standoff pads 220 can form a gap 300 at a periphery 302 (FIG. 3) of the standoff 202 where the standoff 202 is separated from the printed wiring board top surface 216. The gap 300 can extend between the printed wiring board top surface 216 and the standoff bottom surface 218 at the periphery 302. As can be seen with reference to FIG. 3, the adhesive 214 can be dispensed within the gap 300 between the printed wiring board top surface 216 and the standoff bottom surface 218. Moreover, the gap 300 can be dispensed around an entire periphery of the standoff 202 such that the gap 300 is formed around the entire periphery of the standoff 202, as shown with reference to FIG. 6B.

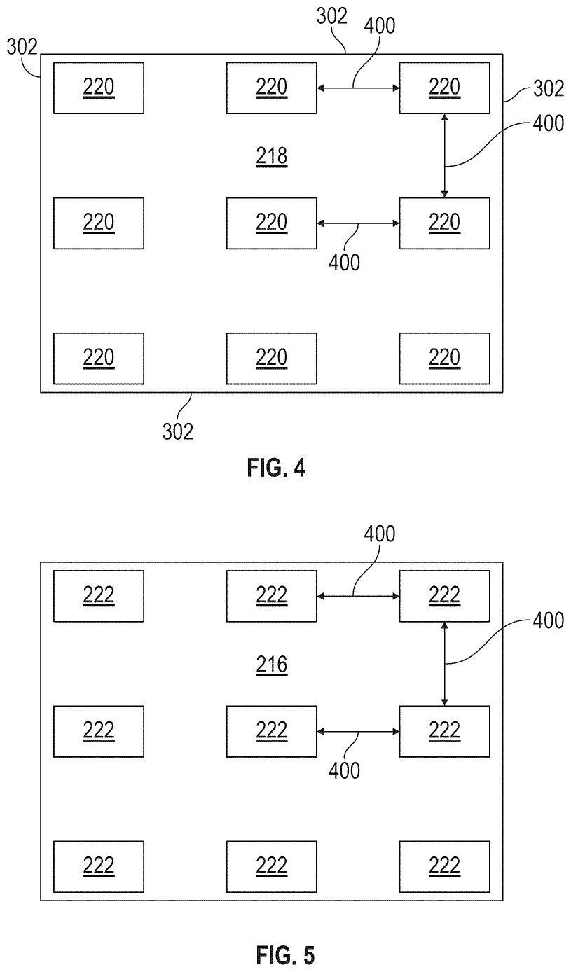

Making reference to FIG. 4, the standoff pads 220 can form a pattern where the standoff pads 220 form a three-by-three array pattern. In the standoff pattern of FIG. 4, the standoff pads 220 can be evenly spaced from each other at a distance 400 at the standoff bottom surface 218. The standoff pads 220 can be formed from a conductive material, such as gold. In further examples, the standoff pads 220 can be formed from a metal alloy typically used to form solder such that the standoff pads 220 can be formed from solder.

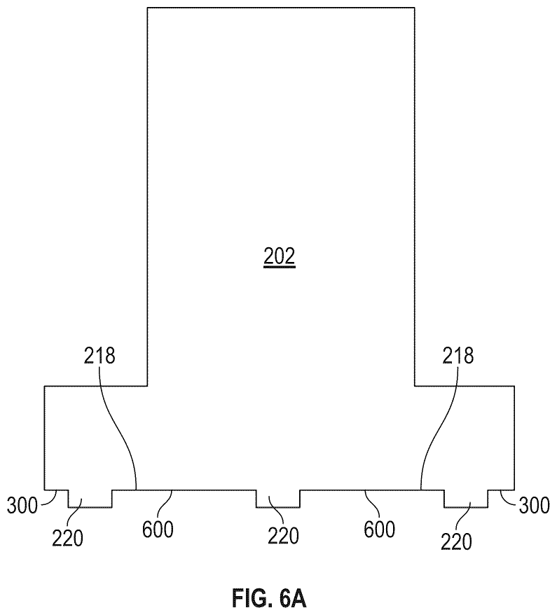

Referring back to FIG. 2, soldering points 222 can extend into the printed wiring board 206 from the printed wiring board top surface 216. As can be seen with reference to FIG. 5, which is a top view of the printed wiring board 206, the soldering points 222 can form a soldering point pattern. Similar to the standoff pads 220, the soldering points 222 can form a three-by-three array pattern. In the pattern of FIG. 5, the soldering points 222 can be evenly spaced from each other at the distance 400 within the printed wiring board 206. The evenly spaced pattern can extend to the printed wiring board top surface 216. Thus, the soldering point pattern can match the standoff pattern. The soldering points 222 can be formed from a metal alloy such that the soldering points 222 are formed from solder. In further examples, the soldering points 222 can be formed from gold or any other conductive material.

By virtue of the standoff pads 220 and the soldering points 222 having the same pattern where each of the standoff pads 220 and each of the soldering points 222 are separated by the distance 400, when the standoff 202 mounts to the printed wiring board 206, the standoff pads 220 can align with the soldering points 222. As such, the standoff pads 220 can electrically couple with the soldering points 222 when the standoff 202 is mounted on the printed wiring board 206. The soldering points 222 can couple to ground. Therefore, the standoff pads 220 can connect to ground via the soldering points 222 thereby connecting the standoff 202 to ground.

By virtue of extending from the standoff bottom surface 218, the standoff pads 220 can also form cavities 600 at the standoff bottom surface 218, as shown with reference to FIGS. 6A and 6B. As shown with regards to FIGS. 6A and 6B and the dashed lines (FIG. 6B), the cavities can be defined between the standoff pads 220 and the standoff bottom surface 218. The adhesive 214 can be disposed within the cavities 600 along with the gap 300 when the standoff 202 is mounted on the printed wiring board 206. In examples, the adhesive can be dispensed in the entirety of the cavities 600 and the gap 300. Furthermore, a portion 304 (FIG. 3) of the adhesive 214 can be disposed outside of the standoff 202 and around the periphery 302. By virtue of being an adhesive, such as when the adhesive 214 is an epoxy, when the adhesive 214 is within the gap 300 and the cavities 600 and contacting the printed wiring board top surface 216 along with the standoff bottom surface 218, the adhesive 214 can secure the standoff 202 to the printed wiring board 206.

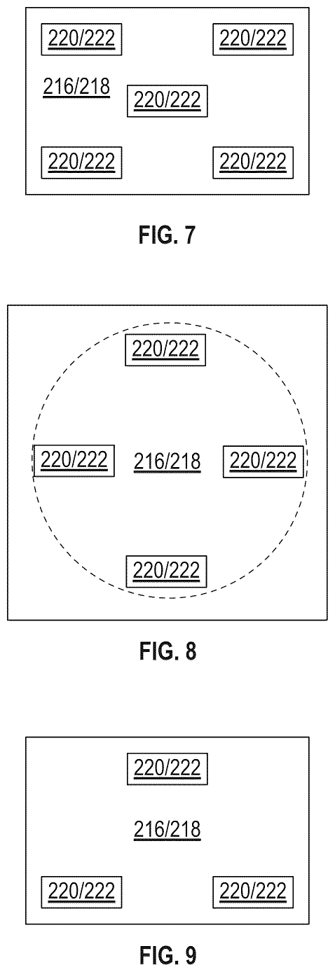

In the examples above, the soldering point pattern and the pad pattern each had a three-by-three array pattern that formed a square configuration. Alternatively, the soldering point pattern and the pad pattern can have a square configuration defined by five stand off pads and five soldering points, as shown with reference to FIG. 7. The soldering point pattern and the pad pattern can also have a circular configuration as shown with reference to FIG. 8. In the circular configuration, while four standoff pads 220/soldering points 222 are shown, there can be any number of standoff pads 220 and any number of matching soldering points 222 such that the soldering points 222 form a circular configuration (as defined by the dashed line) at the printed wiring board top surface 216 and the standoff pads 220 form a circular configuration at the standoff bottom surface 218.

Moreover, the soldering point pattern and the pad pattern can have a triangular configuration as shown with reference to FIG. 9. In the triangular configuration, while three standoff pads 220/soldering points 222 are shown, there can be any number of standoff pads 220 and any number of matching soldering points 222 such that the soldering points 222 form a triangular configuration at the printed wiring board top surface 216 and the standoff pads 220 form a triangular configuration at the standoff bottom surface 218.

In each of FIGS. 6A, 6B, and 7-9, it is to be understood that the pad pattern of the standoff pads 220 matches the soldering point pattern of the soldering points 222 such that the standoff pads 220 align with the soldering points 222.

### Additional Examples

Example 1 is an assembly comprising: a printed wiring board having a top surface; a plurality of soldering points extending into the printed wiring board from the printed wiring board top surface, wherein the plurality of soldering points form a soldering point pattern; a standoff mounted on the printed wiring board top surface, the standoff being configured to thermally couple a cooling plate to the printed wiring board; a plurality of pads extending from a bottom surface of the standoff to the printed wiring board top surface, wherein: the standoff is separated from the printed wiring board by the plurality of pads; a gap is provided by the plurality of pads between the printed wiring board and a periphery of the standoff; the plurality of pads comprise a conductive material; the plurality of pads are provided in a pad pattern at the standoff bottom surface that matches the soldering point pattern such that ones of the plurality of pads align with ones of the plurality of soldering points and the ones of the plurality of pads electrically contact the ones of the plurality of soldering points when the standoff is mounted on the printed wiring board; and cavities are formed between the ones of the plurality of pads by the plurality of pads when the standoff is mounted on the printed wiring board; and an epoxy disposed in the gap between the printed wiring board and the standoff and the cavities, the epoxy securing the standoff with the printed wiring board.

In Example 2, the subject matter of Example 1 includes, wherein the plurality of pads is formed of gold.

In Example 3, the subject matter of Examples 1-2 includes, wherein each of the soldering point pattern and the pad pattern form a triangular configuration.

In Example 4, the subject matter of Examples 1-3 includes, wherein each of the soldering point pattern and the pad pattern form a square configuration.

In Example 5, the subject matter of Examples 1-4 includes, wherein each of the soldering point pattern and the pad pattern form a circular configuration.

In Example 6, the subject matter of Examples 1-5 includes, wherein the standoff couples with the cooling plate at a top surface of the standoff opposite the standoff bottom surface.

In Example 7, the subject matter of Examples 1-6 includes, wherein the standoff connects to ground via the plurality of pads and the plurality of soldering points.

In Example 8, the subject matter of Examples 1-7 includes, wherein the plurality of pads is formed of gold.

Example 9 is an assembly comprising: a printed wiring board having a top surface; a plurality of soldering points extending into the printed wiring board from the printed wiring board top surface, wherein the plurality of soldering points form a soldering point pattern; a standoff mounted on the printed wiring board top surface, the standoff being configured to thermally couple a cooling plate to the printed wiring board; a plurality of pads extending from a bottom surface of the standoff to the printed wiring board top surface, wherein: the standoff is separated from the printed wiring board by the plurality of pads; a gap is formed between the printed wiring board and a periphery of the standoff by the plurality of pads; the plurality of pads comprise a conductive material; and cavities are formed between ones of the plurality of pads by the plurality of pads when the standoff is mounted on the printed wiring board; and an epoxy disposed in the gap between the printed wiring board and the standoff and the cavities, the epoxy securing the standoff with the printed wiring board.

In Example 10, the subject matter of Example 9 includes, wherein the plurality of pads form a pad pattern at the standoff bottom surface that matches the soldering point pattern such that ones of the plurality of pads align with ones of the plurality of soldering points and the ones of the plurality of pads electrically contact the ones of the plurality of soldering points when the standoff is mounted on the printed wiring board.

In Example 11, the subject matter of Example 10 includes, wherein the standoff couples with the cooling plate at a top surface of the standoff opposite the standoff bottom surface.

In Example 12, the subject matter of Examples 10-11 includes, wherein the standoff connects to ground via the plurality of pads and the plurality of soldering points.

In Example 13, the subject matter of Examples 10-12 includes, wherein each of the soldering point pattern and the pad pattern form one of a triangular configuration, a square configuration, or a circular configuration.

In Example 14, the subject matter of Examples 9-13 includes, wherein the plurality of pads is formed of gold.

Example 15 is an assembly comprising: a printed wiring board having a top surface; a plurality of soldering points extending into the printed wiring board from the printed wiring board top surface, wherein the plurality of soldering points form a soldering point pattern; a standoff mounted on the printed wiring board top surface, the standoff being configured to thermally couple a cooling plate to the printed wiring board; a plurality of pads extending from a bottom surface of the standoff to the printed wiring board top surface, wherein: the plurality of pads form a pad pattern at the standoff bottom surface that matches the soldering point pattern such that ones of the plurality of pads align with ones of the plurality of soldering points and the ones of the plurality of pads electrically contact the ones of the plurality of the soldering points when the standoff is mounted on the printed wiring board; a gap is formed between the printed wiring board and a periphery of the standoff by the plurality of pads; and cavities are formed between the ones of the plurality of pads the plurality of pads when the standoff is mounted on the printed wiring board; and an epoxy disposed in the gap between the printed wiring board and the standoffs and the cavities, the epoxy securing the standoff with the printed wiring board.

In Example 16, the subject matter of Example 15 includes, wherein the plurality of pads comprise a conductive material and separate the standoff from the printed wiring board.

In Example 17, the subject matter of Example 16 includes, wherein the standoff couples with the cooling plate at a top surface of the standoff opposite the standoff bottom surface.

In Example 18, the subject matter of Examples 16-17 includes, wherein the standoff connects to ground via the plurality of pads and the plurality of soldering points.

In Example 19, the subject matter of Examples 16-18 includes, wherein each of the soldering point pattern and the pad pattern form one of a triangular configuration, a square configuration, or a circular configuration.

Example 20 is an apparatus comprising means to implement any of Examples 1-19.

Example 21 is a method to implement any of Examples 1-20.

Although teachings have been described with reference to specific example teachings, it will be evident that various modifications and changes may be made to these teachings without departing from the broader spirit and scope of the teachings. Accordingly, the specification and drawings are to be regarded in an illustrative rather than a restrictive sense. The accompanying drawings that form a part hereof, show by way of illustration, and not of limitation, specific teachings in which the subject matter may be practiced. The teachings illustrated are described in sufficient detail to enable those skilled in the art to practice the teachings disclosed herein. Other teachings may be utilized and derived therefrom, such that structural and logical substitutions and changes may be made without departing from the scope of this disclosure. This Detailed Description, therefore, is not to be taken in a limiting sense, and the scope of various teachings is defined only by the appended claims, along with the full range of equivalents to which such claims are entitled.

What is claimed is:

1. An assembly comprising:
a printed wiring board having a top surface;
a plurality of soldering points extending into the printed wiring board from the printed wiring board top surface, wherein the plurality of soldering points form a soldering point pattern;
a standoff mounted on the printed wiring board top surface, the standoff being configured to thermally couple a cooling plate to the printed wiring board;
a plurality of pads extending from a bottom surface of the standoff to the printed wiring board top surface, wherein:
the standoff is separated from the printed wiring board by the plurality of pads;
a gap is provided by the plurality of pads between the printed wiring board and a periphery of the standoff;
the plurality of pads comprise a conductive material;
the plurality of pads are provided in a pad pattern at the standoff bottom surface that matches the soldering point pattern such that ones of the plurality of pads align with ones of the plurality of soldering points and the ones of the plurality of pads electrically contact the ones of the plurality of soldering points when the standoff is mounted on the printed wiring board; and
cavities are formed between the ones of the plurality of pads by the plurality of pads when the standoff is mounted on the printed wiring board; and
an epoxy disposed in the gap between the printed wiring board and the standoff and the cavities, the epoxy securing the standoff with the printed wiring board.

2. The assembly of claim 1, wherein the plurality of pads is formed of gold.

3. The assembly of claim 1, wherein each of the soldering point pattern and the pad pattern form a triangular configuration.

4. The assembly of claim 1, wherein each of the soldering point pattern and the pad pattern form a square configuration.

5. The assembly of claim 1, wherein each of the soldering point pattern and the pad pattern form a circular configuration.

6. The assembly of claim 1, wherein the standoff couples with the cooling plate at a top surface of the standoff opposite the standoff bottom surface.

7. The assembly of claim 1, wherein the standoff connects to ground via the plurality of pads and the plurality of soldering points.

8. The assembly of claim 1, wherein the plurality of pads is formed of gold.

9. An assembly comprising:
a printed wiring board having a top surface;
a plurality of soldering points extending into the printed wiring board from the printed wiring board top surface, wherein the plurality of soldering points form a soldering point pattern;
a standoff mounted on the printed wiring board top surface, the standoff being configured to thermally couple a cooling plate to the printed wiring board;
a plurality of pads extending from a bottom surface of the standoff to the printed wiring board top surface, wherein:
the standoff is separated from the printed wiring board by the plurality of pads;
a gap is formed between the printed wiring board and a periphery of the standoff by the plurality of pads;
the plurality of pads comprise a conductive material; and
cavities are formed between ones of the plurality of pads by the plurality of pads when the standoff is mounted on the printed wiring board; and
an epoxy disposed in the gap between the printed wiring board and the standoff and the cavities, the epoxy securing the standoff with the printed wiring board.

10. The assembly of claim 9, wherein the plurality of pads form a pad pattern at the standoff bottom surface that matches the soldering point pattern such that ones of the plurality of pads align with ones of the plurality of soldering points and the ones of the plurality of pads electrically contact the ones of the plurality of soldering points when the standoff is mounted on the printed wiring board.

11. The assembly of claim 10, wherein the standoff couples with the cooling plate at a top surface of the standoff opposite the standoff bottom surface.

12. The assembly of claim 10, wherein the standoff connects to ground via the plurality of pads and the plurality of soldering points.

13. The assembly of claim 10, wherein each of the soldering point pattern and the pad pattern form one of a triangular configuration, a square configuration, or a circular configuration.

14. The assembly of claim 9, wherein the plurality of pads is formed of gold.

15. The assembly of claim 9, wherein the plurality of pads is formed of gold.

16. An assembly comprising:
a printed wiring board having a top surface;
a plurality of soldering points extending into the printed wiring board from the printed wiring board top surface, wherein the plurality of soldering points form a soldering point pattern;
a standoff mounted on the printed wiring board top surface, the standoff being configured to thermally couple a cooling plate to the printed wiring board;
a plurality of pads extending from a bottom surface of the standoff to the printed wiring board top surface, wherein:
the plurality of pads form a pad pattern at the standoff bottom surface that matches the soldering point pattern such that ones of the plurality of pads align with ones of the plurality of soldering points and the ones of the plurality of pads electrically contact the ones of the plurality of the soldering points when the standoff is mounted on the printed wiring board;
a gap is formed between the printed wiring board and a periphery of the standoff by the plurality of pads; and
cavities are formed between the ones of the plurality of pads the plurality of pads when the standoff is mounted on the printed wiring board; and
an epoxy disposed in the gap between the printed wiring board and the standoffs and the cavities, the epoxy securing the standoff with the printed wiring board.

17. The assembly of claim 16, wherein the plurality of pads comprise a conductive material and separate the standoff from the printed wiring board.

18. The assembly of claim 17, wherein the standoff couples with the cooling plate at a top surface of the standoff opposite the standoff bottom surface.

19. The assembly of claim 17, wherein the standoff connects to ground via the plurality of pads and the plurality of soldering points.

20. The assembly of claim 17, wherein each of the soldering point pattern and the pad pattern form one of a triangular configuration, a square configuration, or a circular configuration.
